(19) United States
(12) Patent Application Publication
(10) Pub. No.: US 2013/0112273 A1
(43) Pub. Date: May 9, 2013

(54) SOLAR CELL

(71) Applicants: Takayuki Negami, Osaka (JP); Teruaki Yamamoto, Ibaraki (JP)

(72) Inventors: Takayuki Negami, Osaka (JP); Teruaki Yamamoto, Ibaraki (JP)

(73) Assignee: PANASONIC CORPORATION, Osaka (JP)

(21) Appl. No.: 13/810,604

(22) PCT Filed: Jun. 7, 2011
(86) PCT No.: PCT/JP2011/063047

§ 371 Date: Jan. 16, 2013

(30) Foreign Application Priority Data
Sep. 13, 2010 (JP) 2010-204615

(51) Int. Cl. H01L 31/0264

(52) U.S. Cl. CPC H01L 31/0264
USPC 136/260; 136/252; 136/265; 136/264; 136/262

(57) ABSTRACT

The present invention provides a semiconductor film which adapts to the solar cell in both of band gap and electric resistivity or carrier concentration.

In the present invention, a semiconductor film is composed of a semiconductor including group 11 elements, group 12 elements, group 13 elements and group 16 element of the ratio indicated as a composition formula (1) in below,

AₓB_{y}C_{z}D_{w} (1)

wherein A, B, C and D indicate said group 11 elements, said group 12 elements, said group 13 elements and said group 16 elements, respectively, x, y, z and w are respectively numbers indicating a composition ratio, and x and z satisfy a relationship of x/z>1.

### TECHNICAL FIELD

The present invention relates to a semiconductor film and a solar cell comprising the semiconductor film.

### BACKGROUND ART

For high-efficiency of solar cell, a multi-junction solar cell stacked plurality of solar cells which absorb lights of each short wavelength region, medium wavelength range and long wavelength region is expected. An efficiency of the multi-junction solar cell is dominated most effectively by an efficiency of the solar cell for short wavelength region (top cell) which the light incidents first. Therefore, it is most important that the top cell is improved so as to have high-efficiency.

A band gap of semiconductor having a chalcopyrite structure is controlled by being elected accordingly form group 11 elements, group 13 elements and group 16 elements. Therefore, a semiconductor layer which adapts to the top cell and absorbs the light of the short wavelength region can be formed of the semiconductor. However, as the band formed of the semiconductor which has chalcopyrite structure is employed Cu(In, Ga)Se₂, CuGaSe₂, CuInS₂ and/or Cu(In,Ga)S₂ which have 1.3 eV or more, the band gap of semiconductor becomes larger, and an actual conversion efficiency of the solar cell reduces dramatically comparing to a theoretical value of the conversion efficiency of the solar cell. As one reason, it is thought that a ratio of increasing of open-circuit voltage is reduced by a broken proportionality relation between a magnifying of the band gap and a increasing of the open-circuit voltage.

On the other hand, it is disclosed that an open-circuit voltage of solar cell is improved by a doping Zn in a semiconductor film in the non-patent document 1. However, the non-patent document 1 discloses that the magnifying of band gap is not found even if being doped in 0.02 of ratio of Zn to Cu, too. Additionally, a short-circuit current density of the solar cell is reduced by doping Zn in the semiconductor film As a reason of above problem, it is thought that a carrier concentration is reduced by the doping Zn. Although the non-patent document 1 does not disclose a molar ratio of Cu to In of CuInS₂ where Zn is doped, it seems that the molar ratio of Cu to In becomes 1 because KCN treatment is carried out. Additionally, for example, the patent document 1 discloses the doping Zn to a surface of a Cu(In, Ga)Se₂ film in order to transform the surface of Cu(In, Ga)Se₂ film of p-type to n-type. However, the molar ratio of Cu to (In+Ga) of the surface of Cu(In, Ga)Se₂ film where Zn is doped is less than 1.

### PRIOR ART DOCUMENTS

### Patent Document

Patent document 1: Japan patent published application No. 6-45248

### Non-Patent Document

Non-patent document 1: D. Braunger, Th. Durr, D. Hariskos, Ch. Koble, Th. Walter, N. Wieser, and H W Schock, “IMPROVED OPEN CIRCUIT VOLTAGE IN CulnS₂-BASED SOLAR CELLS”, Proceedings of 25th IEEE Photovoltaic Specialists Conference, Washington D.C., p. 1001 (1996).

### SUMMARY OF THE INVENTION

### Problems that the Invention is to Solve

As described above, for improving so that the multi-junction solar cell has high efficiency, there are needs of a controlling the carrier concentration and a controlling a band gap of a photo-absorbing layer adapting to the top cell, but in the previous semiconductor having the chalcopyrite structure and consisting of group 11 elements, group 13 elements and group 16 elements, the carrier concentration is reduced when the band gap magnifies. Consequently, it is difficult to control both of the band gap and the carrier concentration. Moreover, when the band gap becomes 1.3 eV or more, there is a problem that a gap density is increased while the band gap magnifies.

The present invention has been made in view of the circumstances described above, and has a purpose to provide a semiconductor film which adapts to solar cell in both of band gap and an electric resistivity or the carrier concentration; and a solar cell, which has a high energy conversion efficiency, comprising the semiconductor film.

### Means for Solving the Problems

A semiconductor film of the present invention is composed of a semiconductor comprising: group 11 elements, group 12 elements, group 13 elements and group 16 elements of the ratio indicated as a composition formula (1) in below.

AₓB_{y}C_{z}D_{w} (1)

wherein A, B, C and D indicate said group 11 elements, said group 12 elements, said group 13 elements and said group 16 elements, respectively, x, y, z and w are respectively numbers indicating a composition ratio, and x and z satisfy a relationship of x/z>1.

In a semiconductor film of the present invention, x and z of said composition formula (1) preferably satisfy a relationship indicated in below.

1<x/z≦2

In a semiconductor film of the present invention, x, y and z of said composition formula (I) preferably satisfy a relationship indicated in below.

0<y/(x+y+z)≦0.6

In a semiconductor film of the present invention, x, y, z and w of said composition formula (1) preferably satisfy a relationship indicated in below.

0.8≦w/(x+y+z)≦1.2

In a semiconductor film of the present invention, said semiconductor preferably comprises: at least either one of Cu and Ag as said group 11 elements, at least either one of Zn and Cd as said group 12 elements, at least any one of In, Ga and Al as said group 13 elements, and at least any one of S, Se and Te as said group 16 elements.

A semiconductor film of the present invention preferably comprises group 1 elements.

A semiconductor film of the present invention preferably comprises group 2 elements.

A semiconductor film of the present invention preferably comprises an oxygen.

A semiconductor film of the present invention preferably has a chalcopyrite structure.

A semiconductor film of the present invention preferably has a p-type semiconductor property.

A semiconductor film of the present invention preferably has an electric resistivity of 1 to 10⁷ Ωcm.

A semiconductor film of the present invention preferably has a carrier concentration of 10¹¹ to 10¹⁹/cm³.

A solar cell of the present invention preferably precomprises: said semiconductor film as a photo-absorbing layer.

In a solar cell of the present invention, said semiconductor film preferably has a band gap of 1.0 to 2.0 eV.

### Effect of the Present Invention

In the present invention, the semiconductor film which adapts to a solar cell in both in both of band gap and an electric resistivity or the carrier concentration can be obtained.

In the present invention, the solar cell which has high energy conversion efficiency can be obtained because the semiconductor film is employed as a photo-absorbing layer of the solar cell.

### BRIEF DESCRIPTION OF THE DRAWINGS

FIG. 1 shows a schematic cross-sectional view representing a first example of the solar cell of the present invention.

FIG. 2 shows a schematic cross-sectional view representing a second example of the solar cell of the present invention.

FIG. 3 shows a graph representing a relationship between the molar ratio of Zn to (Cu+In+Zn) of CuₓZn_{y}In_{z}S_{w} film and the value of band gap.

FIG. 4 shows a graph representing a relationship between a peak intensity and the molar ratio of Cu to In of CuₓZn_{y}In_{z}S_{w} film.

FIG. 5 shows a graph representing a relationship between an electric resistivity and the molar ratio of Cu to In of CuₓZn_{y}In_{z}S_{w} film.

FIG. 6 shows a graph representing a relationship between the molar ratio of Cu to In of CuₓZn_{y}In_{z}S_{w} film and the conversion efficiency of the solar cell comprising the CuₓZn_{y}In_{z}S_{w} film as the photo-absorbing layer.

FIG. 7 shows a graph representing a relationship between the molar ratio of Cu to In of the CuₓZn_{y}In_{z}S_{w} film and a series resistance of the solar cell comprising the CuₓZn_{y}In_{z}S_{w} film as the photo-absorbing layer.

### MODE FOR CARRYING OUT THE INVENTION

The semiconductor film of this embodiment is composed of a semiconductor containing group 11 elements, group 12 elements, group 13 elements and group 16 elements in a rate indicated by a composition formula (1) as shown in below.

AₓB_{y}C_{z}D_{w} (1)

In the composition formula (1), A, B, C and D are indicated as group 11 elements, group 12 elements, group 13 elements and group 16 elements, respectively. Each of x, y, z and w indicates a number of a composition ratio.

In the composition formula (1), x and z satisfies a relationship indicated as x/z>1. Consequently, in the semiconductor composing a semiconductor film, a ratio of group 11 elements is larger than a ratio of group 13 elements.

In the semiconductor film, since a composition ratio of group 12 elements is adjusted, the band gap is controlled easy. In generally, when the composition ratio of group 12 elements of the semiconductor increases, the electric resistivity of semiconductor film increases, or the carrier concentration is reduced. However, in this embodiment, increasing the electric resistivity of semiconductor film and reducing the carrier concentration are controlled. Specifically, since the ratio of group 11 elements is larger than the ratio of group 13 elements in the semiconductor composing the semiconductor film, it is thought that the electric resistivity of semiconductor film reduces, or that the carrier concentration increases. Consequently, even if the semiconductor film is a short wavelength photo-absorbing semiconductor film which has large band gap, the electric resistivity of semiconductor film reduces, or the carrier concentration increases. In the case that the semiconductor film is provided to the solar cell absorbing the light of short wavelength especially, the efficiency of solar cell is increased.

Since the ratio of group 11 elements is larger than the ratio of group 13 elements in the semiconductor, a crystal growth of the semiconductor is promoted, and the gap density is reduced. Therefore, since a recombination of the carrier in the semiconductor is inhibited, in this case also, the efficiency of solar cell is increased when the semiconductor film is provided to the solar cell.

A semiconductor consisting of group 11 elements, group 13 elements and group 16 elements is disclosed in Japan patent published application No. 7-211930 as a prior art. The above semiconductor is configured to generate over amount of low resistance compound consisting of group 11 elements and group 16 elements because the ratio of group 11 elements is larger than the ratio of group 13 elements. When the low resistance compound precipitates on a contacting surface between the semiconductor film composed of semiconductor and a n-type semiconductor, or a grain boundary in the semiconductor film, p-n combination is not formed by a short circuit. Previously, the ratio of group 11 elements in the semiconductor provided to the solar cell is adjusted so as to be a little lower than the ratio of group 13 elements. However, in the semiconductor film of this embodiment, even if the ratio of group 11 elements is larger than the ratio of group 13 elements within the semiconductor, a reducing of property such as the short circuit is inhibited when the semiconductor is provided to, for example, the solar cell. As a reason, holes are generated by being low ratio of group 13 elements within the semiconductor, and the holes are filled by the group 12 elements. Consequently, it is thought that the generation of the low resistance compound is inhibited.

Although a maximum value of x to z in the composition formula (1) is not especially limited, the maximum value is preferably 2 or less. Specifically, x and z in the composition formula (1) preferably satisfies a relationship indicated as in below.

1<x/z≦2

Under this condition, the crystal growth of semiconductor is promoted and the gap density is reduced. Consequently, the carrier concentration within the semiconductor film is especially increased. Additionally, when the value of x to z is increased, the crystal growth is further promoted by excessive group 11 elements. As a result, a roughness (irregularity) of surface of the semiconductor film is increased easy. Therefore, a thickness of the semiconductor film becomes to be generated too thin parts easy. In these parts, there is a problem to generate the short circuit between layers provided to both sides of the semiconductor film. From the view point of inhibiting the short circuit, the value of x to z is preferably 2 or less.

Moreover, about the composition ratio of group 12 elements, the values of x, y and z in the composition formula (1) preferably satisfies a relationship indicated as in below.

0<y/(x+y+z)≦0.6

When the composition ratio of group 12 elements is adjusted in above range, the band gap of semiconductor film is adjusted easy, and the reducing of carrier concentration with the magnifying the band gap of semiconductor film is especially inhibited. Although the band gap becomes larger with the increasing the value of y to (x+y+x), from a view point that the band gap becomes to have a preferable value for the solar cell, the value of y to (x+y+x) preferably becomes 0.6 or less. When the value of y to (x+y+x) becomes larger, a crystal structure of the semiconductor transforms from the chalcopyrite structure to a sphalerite structure. With this transforming, a photo-absorption coefficient is reduced. Consequently, there is need that the thickness of photo-absorbing layer becomes large in order to keep the efficiency of solar cell. Therefore, from a view point of increasing the efficiency of solar cell, too, the value of y to (x+y+x) preferably becomes 0.6 or less.

About the composition ratio of group 16 elements, the values of x, y, z and w in the composition formula (1) preferably satisfies a relationship indicated as in below.

0.8≦w/(x+y+z)

As aforementioned, when the composition ratio of group 16 elements is adjusted, the gap within the semiconductor is further inhibited, and the efficiency of solar cell is further improved in the case that the semiconductor film is provided to the solar cell. Although the value of w to (x+y+z) is not especially limited, the maximum of this value is actually 1.2 because it is difficult to obtain the semiconductor film having larger than 1.2. In short, the values of x, y, z and w especially satisfy a relationship indicated as in below.

0.8≦w/(x+y+z)≦1.2

Although a combination of group 11 elements (A), group 12 elements (B), group 13 elements (C) and group 16 elements (D) in the composition formula (1) is accordingly set, especially, the group 11 elements (A) preferably includes at least either one of Cu and Ag, the group 12 elements (B) preferably includes at least either one of Zn and Cd, the group 13 elements (C) preferably includes at least one kind of In, Ga and Al, and the group 16 elements (D) preferably includes at least one kind of S, Se and Te. When the semiconductor film is composed of the semiconductor having the composition, the band gap of semiconductor corresponds to solar spectrum, and the semiconductor film becomes to adapt to the solar cell especially. The group 11 elements (A), group 12 elements (B), group 13 elements (C) and group 16 elements (D) in the composition formula (1) especially preferably consists of only elements indicated above. Consequently, the group 11 elements (A) especially preferably includes at least either one of Cu and Ag, the group 12 elements (B) especially preferably includes at least either one of Zn and Cd, the group 13 elements (C) especially preferably includes at least one kind of In, Ga and Al, and the group 16 elements (D) especially preferably includes at least one kind of S, Se and Te.

Preferably, the semiconductor film further includes group 1 elements. When the semiconductor film is provided to the solar cell, the efficiency of solar cell is improved. Specifically, the gap of semiconductor is further reduced by the group 1 elements, and the recombination of carrier within the semiconductor film is further inhibited. Herein, Li, Na and K are exemplified as the group 1 elements.

The semiconductor film preferably includes group 2 elements, too. When the semiconductor film is provided to the solar cell, the efficiency of solar cell is further improved because the semiconductor film includes the group 2 elements. The group 2 elements fill holes which the group 12 elements do not exist in the semiconductor, or the group 12 elements of non-combination state is arranged in the crystal lattice of the semiconductor. Whereby, the gap of semiconductor film is further reduced. Herein, Mg and Ca are exemplified as the group 2 elements.

The semiconductor film preferably includes oxygen, too. The efficiency of solar cell is further improved when the semiconductor film is provided to the solar cell. Starved areas of the group 16 elements within the crystal structure of semiconductor are supplemented by oxygen. Whereby, the gap of semiconductor film is further reduced. Additionally, the oxygen are not included in the group 16 elements (D) of the composition formula (1).

The crystal structure of semiconductor composing of the semiconductor film preferably becomes to have the chalcopyrite structure. As aforementioned, when the crystal structure of semiconductor transforms from the chalcopyrite structure to sphalerite structure, the photo-absorption coefficient is reduced with the transforming. Therefore, there is need that the thickness of photo-absorbing layer becomes larger in order to keep the efficiency of solar cell. On the other hand, when the crystal structure of semiconductor film becomes to have the chalcopyrite structure, the photo-absorption coefficient of semiconductor film becomes larger. When the semiconductor film is provided to the solar cell, the light is fully absorbed by the semiconductor film even if the thickness of semiconductor film is thin.

The semiconductor film preferably has a property of p-type semiconductor. In this case, the carrier concentration within the semiconductor film is especially increased by over-amount of the group 11 elements than the amount of the group 13 elements. In order to provide the property of p-type semiconductor to the semiconductor film, the composition and structure of the semiconductor film is designed accordingly. When the semiconductor has the chalcopyrite structure, the semiconductor film becomes to have the property of p-type semiconductor because x and z of the composition formula (1) satisfies a condition indicated as x/z>1, and because the semiconductor composes the semiconductor film.

The electric resistivity of semiconductor film is preferably in the range of 1 to 10⁷ Ωcm, the carrier concentration of semiconductor film is preferably in the range of 10¹¹ to 10¹⁹/cm³. When the semiconductor film is provided to the solar cell, the electric resistivity of semiconductor film becomes to have a value adapting to the solar cell. Under the above mentioned condition, when the semiconductor film is stacked with other layer, specifically, when the photo-absorbing layer is composed by stacking a first semiconductor film having higher electric resistivity and a second semiconductor film having lower electric resistivity, an inside electric field is formed within the photo-absorbing layer, and an electric field layer which promotes a carrier transport is formed. The short circuit is inhibited between the photo-absorbing layer and a layer adjoining the photo-absorbing layer by the first semiconductor film having higher electric resistivity. Additionally, when the first semiconductor film is the semiconductor film of this embodiment, the second semiconductor film having lower electric resistivity may be the semiconductor film in this embodiment and may not be the semiconductor film in this embodiment. The electric resistivity and carrier concentration of the semiconductor film is controlled accordingly by adjusting kinds and composition ratio of group 11 elements, group 12 elements, group 13 elements and group 16 elements within the semiconductor composing the semiconductor film For example, when the ratio of group 11 elements and group 13 elements within the semiconductor, in short, the value of x to z in the composition formula (1) is adjusted, the electric resistivity and carrier concentration of the semiconductor film is adjusted easy.

The band gap of semiconductor film is preferably in the range of 1.0 to 2.0 eV. When the semiconductor film is provided to the solar cell, the semiconductor film especially becomes to have good solar energy conductivity. Especially, in order to obtain the semiconductor film for short wavelength absorption, the band gap of semiconductor film is preferably in the range of 1.5 to 2.0 eV. As aforementioned, even if the band gap becomes larger, the semiconductor film of this embodiment has lower electric resistivity, or the carrier density becomes higher. Therefore, it is possible that the solar cell becomes to have excellent efficiency. The band gap of semiconductor film is controlled when the kinds and composition ratio of the group 11 elements, group 12 elements, group 13 elements and group 16 elements within the semiconductor which composes the semiconductor film are adjusted. In this embodiment, the band gap is controlled easy by adjusting the composition ratio of the group 12 elements within the semiconductor.

The composition of semiconductor composing the semiconductor film is exemplified as in below. CuₓZn_{y}In_{z}S_{w}, CuₓZn_{y}In_{z}Se_{w}, CuₓZn_{y}In_{z}Te_{w}, CuₓZn_{y}Ga_{z}S_{w}, CuₓZn_{y}Ga_{z}Se_{w}, CuₓZn_{y}Ga_{z}Te_{w}, AgₓZn_{y}In_{z}S_{w}, AgₓZn_{y}In_{z}Se_{w}, AgₓZn_{y}In_{z}Te_{w}, AgₓZn_{y}Ga_{z}S_{w}, AgₓZn_{y}Ga_{z}Se_{w}, AgₓZn_{y}Ga_{z}Te_{w}, CuₓCd_{y}In_{z}S_{w}, CuₓCd_{y}In_{z}Se_{w}, CuₓCd_{y}In_{z}Te_{w}, CuₓCd_{y}Ga_{z}S_{w}, CuₓCd_{y}Ga_{z}Se_{w}, CuₓCd_{y}Ga_{z}Te_{w}, AgₓCd_{y}In_{z}S_{w}, AgₓCd_{y}In_{z}Se_{w}, AgₓCd_{y}In_{z}Te_{w}, AgₓCd_{y}Ga_{z}S_{w}, AgₓCd_{y}Ga_{z}Se_{w}, AgₓCd_{y}Ga_{z}Te_{w} and the like. When each values of x, y and z is more than 0 and is 1 or less, the value of w is approximately 2. The semiconductor film may be composed of a solid solution of at least 2 kinds of different compositions.

The semiconductor film is produced by a method according with need. For example, the semiconductor film is formed by the method of spraying thermal degradation using a water solution which includes compounds of each elements of group 11 elements, group 12 elements, group 13 elements and group 16 elements in the ratio according with composition of the semiconductor. As the compounds of each elements of group 11 elements, group 12 elements, group 13 elements and group 16 elements, haloids such as chlorides of each elements described above are cited, or thiourea is exemplified as compounds of S.

In the case that the semiconductor film including the group 1 elements is formed by the method of spraying thermal degradation, for example, as the compounds included in the water solution, a compound of group 1 elements is employed together with compounds of each elements of group 11 elements, group 12 elements, group 13 elements and group 16 elements. When the semiconductor film including the group 2 elements is formed by the method of spraying thermal degradation, for example, as the compounds included in the water solution, a compound of group 2 elements is employed together with compounds of each elements of group 11 elements, group 12 elements, group 13 elements and group 16 elements. When the semiconductor film including the group 1 elements and group 2 elements is formed, the compound of group 1 elements is employed together with the compound of group 2 elements. As the compound of group 1 elements and the compound of group 2 elements, haloids such as chlorides of each elements described above are cited.

As the method of forming the semiconductor film, an evaporation method is also cited. In this case, each elements of group 11 elements, group 12 elements, group 13 elements and group 16 elements becomes an evaporation source, a deposition rate at depositing is controlled in accordance with the composition of semiconductor.

When the semiconductor film including the group 1 elements is formed by the evaporation method, for example, as the evaporation source, the group 1 elements is employed together with the group 11 elements, group 12 elements, group 13 elements and group 16 elements. When the semiconductor film including the group 2 elements is formed by the evaporation method, for example, as the evaporation source, the group 2 elements is employed together with the group 11 elements, group 12 elements, group 13 elements and group 16 elements. When the semiconductor film including the group 1 elements and group 2 elements is formed, as the evaporation source, the group 1 elements are employed together with the group 2 elements.

As a method of obtaining the semiconductor film including the oxygen, a heating in the atmosphere including the oxygen, for example, within the air after forming the film including the group 11 elements, group 12 elements, group 13 elements and group 16 elements by the method described above is cited. The heating temperature is set, for example, in the range of 200 to 400° C. In the crystal composed of the group 11 elements, group 12 elements, group 13 elements and group 16 elements, since the holes where the group 16 elements do not exist is filled by the oxygen, the semiconductor film composed of the semiconductor which includes the oxygen can be obtained.

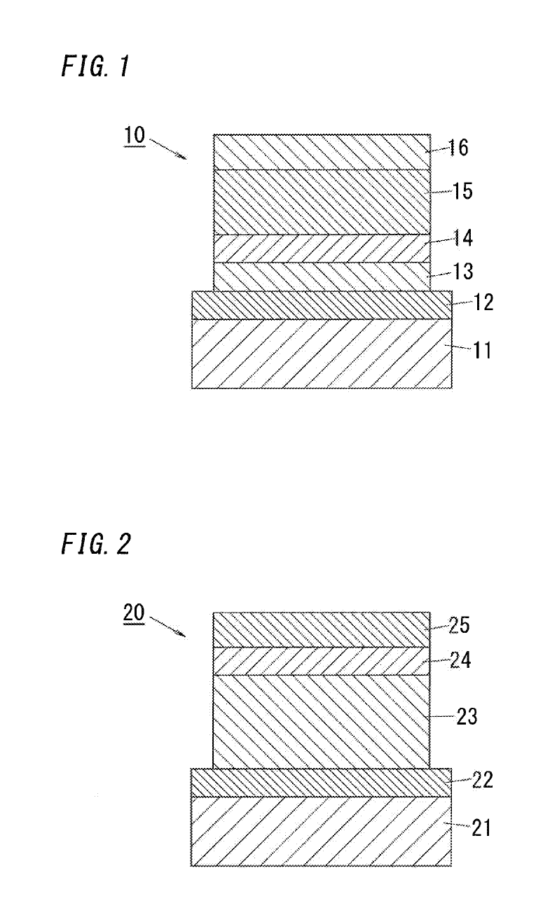

FIG. 1 shows a first example of the solar cell comprising the semiconductor film of this embodiment. The solar cell 10 comprises a base plate 11, a transparent electrode 12, a window layer 13, a buffer layer 14, the photo-absorbing layer 15 and a backside electrode 16. The base plate 11, the transparent electrode 12, the window layer 13, the buffer layer 14, the photo-absorbing layer 15 and the backside electrode 16 are stacked in this order.

The base plate 11 has transparency, and the base plate is formed of, for example, a glass or a transparent resin.

The transparent electrode 12 is formed of, for example, metal oxide. As the metal oxide for forming the transparent electrode 12, for example, SnO₂:F, ZnO:Al, ZnO:Ga, IXO (In₂O₃:X, herein, Sn, Mn, Mo, Ti and Zn are cited as X) and the like are cited. The transparent electrode 12 may be composed by stacking multiple metal oxides. A thickness of the transparent electrode 12 is, for example, in the range of 0.1 to 2.0 micro meters.

The window layer 13 is formed of the semiconductor having a property of n-type or i-type semiconductor. As the semiconductor for forming the window layer 13, ZnO, TiO₂ or the like is cited. The window layer 13 may be composed by stacking multiple semiconductors, and the window layer 13 may have, for example, a structure stacked ZnO and TiO₂. In the window layer 13 which has the structure stacked ZnO and TiO₂, TiO₂ is stacked on a side of the photo-absorbing layer 15 from ZnO, or ZnO is stacked on a side of the photo-absorbing layer 15 from TiO₂. a thickness of the window layer 13 is, for example, in the range of 0.05 to 1.0 micro meters.

The buffer layer 14 is formed of the semiconductor having the property of the n-type or i-type semiconductor. As the semiconductor for forming the buffer layer 14, In₂S₃, Ga₂S₃, Zn(O, 5), Zn₁₋ₓMgₓO, CdS or the like is cited. Herein, x indicated in Zn₁₋ₓMgₓO satisfies a relationship as in below.

0≦x<1

A thickness of the buffer layer 14 is, for example, in the range of 0.05 to 1.0 micro meters.

The photo-absorbing layer 15 is composed of the semiconductor film described above. A thickness of the photo-absorbing layer 15 is, for example, in the range of 0.3 to 3.0 micro meters.

The backside electrode 16 is formed of, for example, metal. As the metal for forming the backside electrode 16, Au, Pt, Ag, Al or the like is cited. The backside electrode 16 may be formed of carbon Like an upper solar cell of tandemtandem solar cell, when transparency is required to the backside electrode 16, the backside electrode 16 may be formed of conductive oxide. As the conductive oxide, for example, a conductive oxide same with the transparent electrode 12; an oxide including cupper such as Cu₂O, CuSr₂O₄ or the like; and Ag₂O or the like are cited. A thickness of the backside electrode 16 is, for example, in the range of 0.1 to 50 micro meters although the thickness is widely different from a material composing the backside electrode 16.

FIG. 2 shows a second example of the solar cell comprising the semiconductor film of this embodiment. The solar cell 20 comprises a base plate 21, a first electrode 22, a photo-absorbing layer 23, a window layer 24 and a second electrode 25. The base plate 21, the first electrode 22, the photo-absorbing layer 23, the window layer 24 and the second electrode 25 are stacked in this order.

Although the base plate 21 may have transparency as well as the base plate 11 of the first example represented in FIG. 1, the base plate 21 may not have transparency. The first electrode 22 is, for example, composed as well as the backside electrode 16 of the first example represented in FIG. 1.

The photo-absorbing layer 23 is composed of the semiconductor film of this embodiment. A thickness of the photo-absorbing layer 23 is, for example, in the range of 0.3 to 3.0 micro meters.

The window layer 24 is, for example, composed as well as the window layer 13 of the first example represented in FIG. 1. The second electrode 25 is, for example, composed as well as the transparent electrode 12 represented in FIG. 1.

The construction of solar cell is not limited in the first and second examples, the semiconductor film of this embodiment can be provided to the well-known solar cells as the photo-absorbing layer.

The semiconductor film of this embodiment is preferably provided to the multi-junction solar cell comprising plurality of photo-absorbing layers which have different absorption wavelength. In the multi-junction solar cell, when the semiconductor film of this embodiment is employed as the photo-absorbing layer of the solar cell (top cell) absorbing the short wavelength region, it is possible to improve so that the top cell has excellent efficiency. Therefore, it is possible to improve so that entire of multi-junction solar cell has excellent efficiency.

### EXAMPLE

### Preparation Example 1 of Semiconductor Film

CuₓZn_{y}In_{z}S_{w} film was formed on a soda-lime glass by the method of spraying thermal degradation. The specification is explained as in below.

As a first step, multiple water solutions including CuCl₂, InCl₃, ZnCl₂ and thiourea are prepared. In theses water solutions, the total molar concentration of CuCl₂, InCl₃ and ZnCl₂ and the concentration of thiourea were adjusted to 4 mmmol/L and 10 mmol/L, respectively, and the molar ratio of Cu to In was adjusted to 1.05. The molar ratio of Zn/(Cu+In+Zn) of the solution was adjusted in the range of 0 to 1. When ZnCl₂ was 0 mmol, the concentration of this solution was prepared to 2 mmol/L as well as the solution including CuCl₂ and InCl₃. In CuInS₂ film which did not include Zn, when the molar ratio of Cu to In was 1 or more, the Cu—S phase was formed by excessive Cu and S. As a result, it was difficult to calculate the band gap of chalcopyrite phase consisting of CuInS₂.

The solution was sprayed on the soda-lime glass plate of 400° C., and the CuₓZn_{y}In_{z}S_{w} film having thickness of 1 micro meter was formed on the soda-lime glass plate. In the molar ratio of constituent of the CuₓZn_{y}In_{z}S_{w} film, results evaluated by Inductively Coupled Plasma Method and wavelength dispersive fluorescence X-ray analysis were summarized in Table 1. In these results, the molar ratio of Zn/(Cu+In+Zn) of the CuₓZn_{y}In_{z}S_{w} film corresponded to approximately molar ratio of Zn/(Cu+In+Zn) within the water solution. Moreover, the molar ratio of S/(Cu+In+Zn) within the CuₓZn_{y}In_{z}S_{w} film was in the range of 0.8 to 1.2.

TABLE 1

| | | | | | The molar ratio |
|---|---|---|---|---|---|
| | The molar ratio | | | | of Zn/ |
| Sample No. | Cu | Zn | In | S | (Cu + In + Zn) |
| 1 | 1 | 0 | 1 | 2.2 | 0 |
| 2 | 1.05 | 0.51 | 1 | 2.65 | 0.2 |
| 3 | 1.05 | 0.88 | 1 | 2.99 | 0.3 |
| 4 | 1.05 | 1.37 | 1 | 3.45 | 0.4 |
| 5 | 1.05 | 3.08 | 1 | 5.05 | 0.6 |
| 6 | 1.05 | 8.2 | 1 | 10 | 0.8 |
| 7 | 0 | 1 | 0 | 1 | 1 |

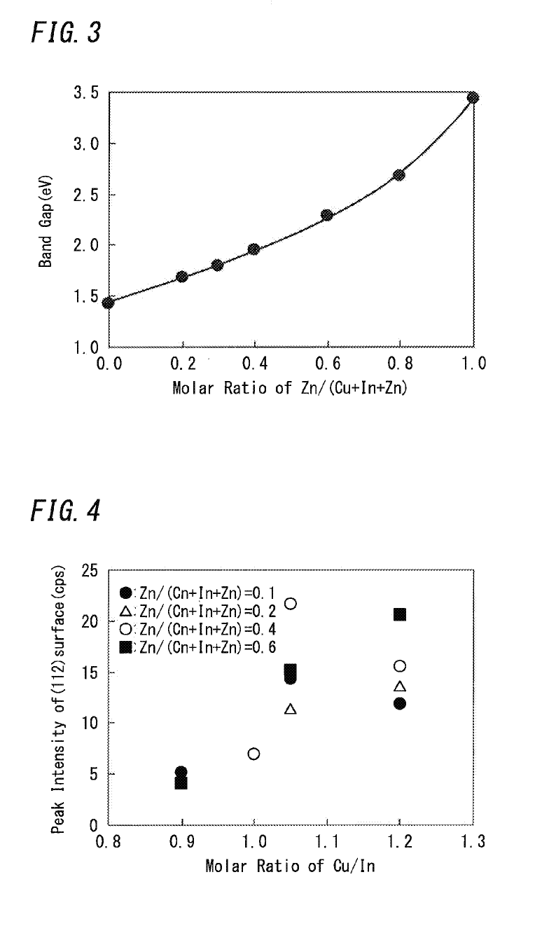

By characterizing transparency of the semiconductor film, the photo-absorption coefficient of semiconductor film was calculated. The value of band gap in the semiconductor film was calculated from the photo-absorption coefficient. FIG. 3 is a graph prepared from the results. FIG. 3 shows a relationship between the molar ratio of Zn/(Cu+In+Zn) of CuₓZn_{y}In_{z}S_{w} film and the value of band gap. From FIG. 3, when the molar ratio of Zn/(Cu+In+Zn) sifts from 0 to 1, it is confirmed that the value of band gap increased linearly from 1.4 eV to 3.4 eV in accordance with this shift.

### Preparation Example 2 of Semiconductor Film

As a first step, multiple water solutions including CuCl₂, InCl₃, ZnCl₂ and thiourea are prepared. In theses water solutions, the total molar concentration of CuCl₂, InCl₃ and ZnCl₂ and the concentration of thiourea were adjusted to 4 mmmol/L and 10 mmol/L, respectively, and the molar ratio of Cu to In in each water solutions was adjusted in the range of 0.9 to 3, and the molar ratio of Zn/(Cu+In+Zn) in each water solutions was adjusted in the range of 0.1 to 0.6.

The water solution was sprayed on the soda-lime glass plate of 350° C., and the CuₓZn_{y}In_{z}S_{w} film having thickness of 1 micro meter was formed on the soda-lime glass plate. In the molar ratio of constituent of the CuₓZn_{y}In_{z}S_{w} film, results evaluated by Inductively Coupled Plasma Method and the wavelength dispersive fluorescence X-ray analysis were summarized in Table 2.

TABLE 2

| Sample | The molar ratio | | | | The molar ratio | The molar ratio of |
|---|---|---|---|---|---|---|
| No. | Cu | Zn | In | S | of Cu/In | Zn/(Cu + In + Zn) |
| 8 | 0.9 | 0.21 | 1 | 2.2 | 0.9 | 0.1 |
| 9 | 0.9 | 0.48 | 1 | 2.44 | 0.9 | 0.2 |
| 10 | 0.9 | 1.27 | 1 | 3.29 | 0.9 | 0.4 |
| 11 | 0.9 | 2.85 | 1 | 4.8 | 0.9 | 0.6 |
| 12 | 1 | 1.33 | 1 | 3.35 | 1 | 0.4 |
| 13 | 1.05 | 0.23 | 1 | 2.4 | 1.05 | 0.1 |
| 14 | 1.05 | 0.51 | 1 | 2.65 | 1.05 | 0.2 |
| 15 | 1.05 | 1.37 | 1 | 3.45 | 1.05 | 0.4 |
| 16 | 1.05 | 3.08 | 1 | 5.05 | 1.05 | 0.6 |
| 17 | 1.2 | 0.24 | 1 | 2.34 | 1.2 | 0.1 |
| 18 | 1.2 | 0.55 | 1 | 2.65 | 1.2 | 0.2 |
| 19 | 1.2 | 1.47 | 1 | 3.57 | 1.2 | 0.4 |
| 20 | 1.2 | 3.3 | 1 | 5.4 | 1.2 | 0.6 |

The x-ray diffraction method was carried out for CuₓZn_{y}In_{z}S_{w} film. From this result, the peak intensity of (112) surface was measured in the case that molar ratios of Zn/(Cu+In+Zn) are 0.1, 0.2, 0.4 and 0.6, respectively. FIG. 4 is a graph prepared from these results. FIG. 4 represents a relationship the peak intensity and the molar ratio of Cu to In of CuₓZn_{y}In_{z}S_{w} film in the case that molar ratios of Zn/(Cu+In+Zn) are 0.1, 0.2, 0.4 and 0.6, respectively. From FIG. 4, it is possible to see a tendency that the peak intensity becomes larger when the molar ratio of Cu to In becomes larger than 1.

The electric resistivity of CuₓZn_{y}In_{z}S_{w} film was measured. The molar ratio of constituent of CuₓZn_{y}In_{z}S_{w} film used for the measurement is summarized in Table 3.

TABLE 3

| | | | | | | The molar ratio |
|---|---|---|---|---|---|---|
| Sample | The molar ratio | | | | The molar ratio | of |
| No. | Cu | Zn | In | S | of Cu/In | Zn/(Cu + In + Zn) |
| 21 | 1.05 | 0.52 | 1 | 2.65 | 1.05 | 0.2 |
| 22 | 1.1 | 0.53 | 1 | 2.65 | 1.1 | 0.2 |
| 23 | 1.2 | 0.55 | 1 | 2.65 | 1.2 | 0.2 |
| 24 | 1.5 | 0.63 | 1 | 2.87 | 1.5 | 0.2 |
| 25 | 2 | 0.75 | 1 | 3.25 | 2 | 0.2 |
| 26 | 3 | 1 | 1 | 4.02 | 3 | 0.2 |
| 27 | 1.1 | 0.9 | 1 | 3.05 | 1.1 | 0.3 |
| 28 | 1.2 | 0.94 | 1 | 3.04 | 1.2 | 0.3 |
| 29 | 1.35 | 1.01 | 1 | 3.18 | 1.35 | 0.3 |
| 30 | 1.5 | 1.07 | 1 | 3.32 | 1.5 | 0.3 |

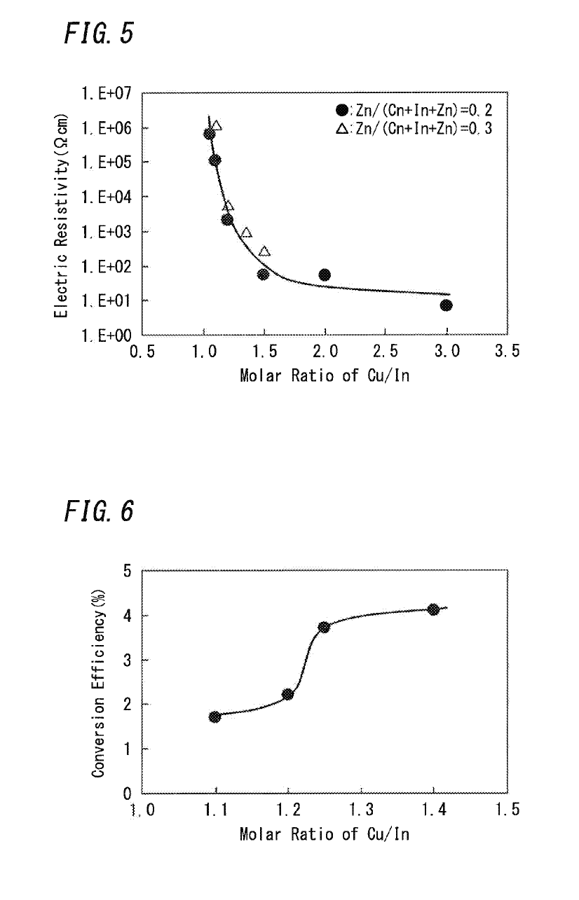

FIG. 5 a graph prepared from these results. FIG. 5 represents a relationship the electric resistivity and the molar ratio of Cu to In of CuₓZn_{y}In_{z}S_{w} film in the case that molar ratios of Zn/(Cu+In+Zn) are 0.2 and 0.3, respectively. FIG. 5 shows that the electric resistivity was reduced according to increasing the molar ratio of Cu to In unrelated to the value of molar ratio of Zn/(Cu+In+Zn). Additionally, the electric resistivity did not almost vary when the molar ratio of Cu to In was 2 or more. The electric resistivity indicated in FIG. 5 shows the variation range of 1 to 10⁷ Ωcm. The variation range of electric resistivity corresponds to the carrier concentration of 10¹¹ to 10¹⁹/cm³ when the variation range was converted to the carrier concentration.

[Evaluation of Semiconductor Film]

From the results of FIG. 3, when the molar ratio of Zn/(Cu+In+Zn) in the CuₓZn_{y}In_{z}S_{w} film was adjusted, it was possible that the band gap of semiconductor film was adjusted easy. Especially, when the molar ratio of Zn/(Cu+In+Zn) was 0.6 or less, the band gap of CuₓZn_{y}In_{z}S_{w} film became 2.5 or less. Consequently, the CuₓZn_{y}In_{z}S_{w} film had especially good value for the photo-absorbing layer of solar cell. Therefore, in order to provide to the solar cell, it is especially preferably that the molar ratio of Zn/(Cu+In+Zn) within the CuₓZn_{y}In_{z}S_{w} film is more than 0 and 0.6 or less.

In CuₓZn_{y}In_{z}S_{w} film, when the molar ratio of Cu to In was larger than 1, specifically, when the relationship indicated as x/y>1 of the composition formula (1) was satisfied, the crystallinity of CuₓZn_{y}In_{z}S_{w} film was improved. Consequently, it is thought that the CuₓZn_{y}In_{z}S_{w} film is preferably provided to the solar cell as the photo-absorbing layer. Additionally, when the molar ratio of Cu to In within the CuₓZn_{y}In_{z}S_{w} film was adjusted, the electric resistivity or carrier concentration of CuₓZn_{y}In_{z}S_{w} film was controlled so as to have good value for improving the conversion efficiency of solar cell.

When the CuₓZn_{y}In_{z}S_{w} film was prepared in the molar ratio of S/(Cu+In+Zn) of less than 0.8 by extremely reducing the concentration of thiourea within water solution at forming the CuₓZn_{y}In_{z}S_{w} film, the peak of (112) of the CuₓZn_{y}In_{z}S_{w} film was not confirmed, and CuₓZn_{y}In_{z}S_{w} film was not crystallized mostly. On the other hand, the molar ratio of S/(Cu+In+Zn) of the CuₓZn_{y}In_{z}S_{w} film did not over-go 1.2 even if extremely increasing the thiourea concentration of water solution.

When the x-ray diffraction method was carried out for the CuₓZn_{y}In_{z}S_{w} film, it was confirmed that the crystal structure of CuₓZn_{y}In_{z}S_{w} film becomes the chalcopyrite structure when the molar ratio of Zn/(Cu+In+Zn) is 0.6 or less.

On the other hand, when the molar ratio of Zn/(Cu+In+Zn) over-went 0.6, it was confirmed that the crystal structure of CuₓZn_{y}In_{z}S_{w} film transformed from the chalcopyrite structure to the sphalerite structure, and there was tendency that the photo-absorption coefficient of CuₓZn_{y}In_{z}S_{w} film was reduced according to the transformation. In this case, there was need that the CuₓZn_{y}In_{z}S_{w} film was formed so as to have thickness of several to dozens micro meters for providing to the solar cell as the photo-absorbing layer. Consequently, there was tendency that the efficiency of solar cell was reduced reason why the carrier diffusion length became shorter than the thickness of photo-absorbing layer.

When LiCl, NaCl, KC1, MgC12 or CaC12 of 0.01 to 0.1 mmol/L was added into the water solution at forming the CuₓZn_{y}In_{z}S_{w} film, it was confirmed that the electric resistivity of CuₓZn_{y}In_{z}S_{w} film was reduced from 10⁻¹ to 0.5 times while the peak intensity of (112) surface by x-ray diffraction method in the case that the molar ratio of Cu to In within the CuₓZn_{y}In_{z}S_{w} film was larger than 1 in comparison with no addition of compound described above. In short, when the group 1 elements or group 2 elements was added in CuₓZn_{y}In_{z}S_{w} film, the crystallinity was improved. Consequently, it is thought that the gap within the crystal is reduced by addition of the group 1 elements or group 2 elements. Therefore, the CuₓZn_{y}In_{z}S_{w} film can be effectively provided to the solar cell as the photo-absorbing layer by adding a bit of the group 1 elements or group 2 elements in the CuₓZn_{y}In_{z}S_{w} film.

### Preparation Example 1 of Solar Cell

In this example, the base plate 11 formed of soda-lime glass was used. ITO was stacked on the base plate 11 by ultrasonic misting, and the transparent electrode 12 having 0.5 micro meters of thickness was formed on the base plate 11.

Next, the window layer 13 consisting of TiO₂ was formed on the transparent electrode 12 by sputtering so as to have 0.1 micro meters of thickness. At this sputtering, the TiO₂ sintered compact was used as target, Ar gas was filled within the instrument for sputtering, and the sputtering was carried out by the applied power of RF400W.

Next, the buffer layer 14 consisting of In₂S₃ was formed on the window layer 13 by the method of spraying thermal degradation so as to have the thickness of approximately 0.1 micro meters. At the spraying, the water solution including InCl₃ of 2 mmol/L and thiourea of 6 mmol/L was sprayed on the window layer 13 heated until 300° C.

Next, the photo-absorbing layer 15 consisting of CuₓZn_{y}In_{z}S_{w} film was formed on the buffer layer 14 by the same method of preparation example 1 and 2 so as to have 1 micro meter. The molar ratio of Zn/(Cu+In+Zn) within the CuₓZn_{y}In_{z}S_{w} film became 0.3, and the molar ratio of Cu to In was varied in the range of 1.1 to 1.4. The molar ratio of constituent of CuₓZn_{y}In_{z}S_{w} film formed over the glass plate by the same method with the photo-absorbing layer 15 was evaluated by Inductively Coupled Plasma Method and wavelength dispersive fluorescence X-ray analysis. These results are summarized in Table 4.

TABLE 4

| Sample | The molar ratio | | | | The molar ratio |
|---|---|---|---|---|---|
| No. | Cu | Zn | In | S | of Cu/In |
| 31 | 1.1 | 0.9 | 1 | 3.05 | 1.1 |
| 32 | 1.2 | 0.94 | 1 | 3.04 | 1.2 |
| 33 | 1.05 | 0.96 | 1 | 3.09 | 1.25 |
| 34 | 1.05 | 1.03 | 1 | 3.23 | 1.4 |

Next, the backside electrode 17 consisting of Au was formed on the photo-absorbing layer 15 by the evaporation method so as to have approximately 0.2 micro meters.

Whereby, the solar cell 10 exemplified in FIG. 1 was obtained.

Additionally, the solar cell comprising a photo-absorbing layer consisting of CuInS₂ film which did not include Zn other than the photo-absorbing layer 15 was also prepared by the same method described above. At forming the CuInS₂ film, the method of spraying thermal degradation was carried out by using the water solution including CuCl₂ of 2 mmol/L, InCl₃ of 2 mmol/L, and thiourea of 10 mmol/L.

The photo-absorption coefficient of photo-absorbing layer 15 was calculated by evaluating the transparency of photo-absorbing layer 15 in the solar cell, and the band gap of photo-absorbing layer 15 was calculated from the photo-absorption coefficient. As a result, when the photo-absorbing layer 15 was formed of the CuₓZn_{y}In_{z}S_{w} film and the molar rate of Zn/(Cu+In+Zn) was 0.3, the band gap of photo-absorbing layer 15 was 1.75 eV. The band gap of photo-absorbing layer 15 formed of CuInS₂ film was 1.45 eV.

The pseudo-solar light (1 kW/m², Air Mass: 1.5) was irradiated to the base plate 11 of solar cell 10, and the property of current-voltage of solar cell was measured at this time. The conductive efficiency of solar cell 10 was evolved. FIG. 6 is a graph prepared from these results. FIG. 6 shows a relationship between the molar ratio of Cu to In of CuₓZn_{y}In_{z}S_{w} film and the conversion efficiency of solar cell 10. According to FIG. 6, it is confirmed that the conductive efficiency of solar cell is improved while the molar ratio of Cu to In of CuₓZn_{y}In_{z}S_{w} film is increased.

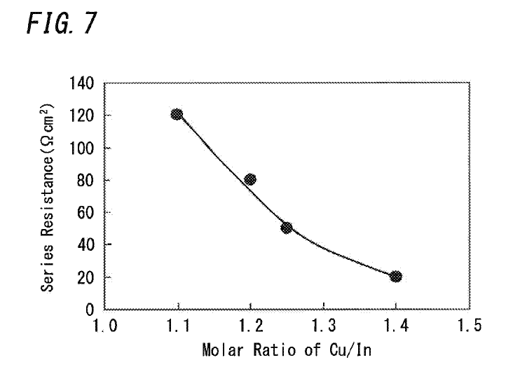

Additionally, the series resistance of each solar cells 10 is measured. FIG. 7 is a graph prepared from these results. FIG. 7 shows a relationship between the molar ratio of Cu to In of CuₓZn_{y}In_{z}S_{w} film and the series resistance of solar cell. From FIG. 7, it is confirmed that the series resistance is reduced while the molar ratio of Cu to In of the CuₓZn_{y}In_{z}S_{w} film is increased.

From these results, when the molar ratio of Cu to In of CuₓZn_{y}In_{z}S_{w} film is increased, the electric resistivity of CuₓZn_{y}In_{z}S_{w} film is reduced, and the carrier concentration is increased. Whereby, the series resistance of solar cell is reduced, and the fill factor is improved. Therefore, it is thought that the conversion efficiency of solar cell is improved.

Additionally, from FIG. 6, when the solar cell comprised the photo-absorbing layer consisting of CuₓZn_{y}In_{z}S_{w} film, the molar ratio of Cu to In of CuₓZn_{y}In_{z}S_{w} film was 1.4, and the conversion efficiency of solar cell was 4.1%. On the other hand, the conversion efficiency of solar cell comprising the photo-absorbing layer which consisted of CuInS₂ was 3.8%. Generally, the band gap of photo-absorbing layer of solar cell was reduced with magnifying of the band gap when the band gap of photo-absorbing layer of solar cell was 1.4 eV or more. However, the conversion efficiency of solar cell 10 was improved even if the band gap of photo-absorbing layer of solar cell was magnified. Therefore, it is possible that the electric resistivity of CuₓZn_{y}In_{z}S_{w} film is controlled by controlling the molar ratio of Cu to In.

From the above, the CuₓZn_{y}In_{z}S_{w} film can be preferably provided to the solar cell 10 as the photo-absorbing layer. Moreover, since it is possible to magnify the band gap of CuₓZn_{y}In_{z}S_{w} film, the solar cell comprising the photo-absorbing layer which consists of CuₓZn_{y}In_{z}S_{w} film can convert to energy through absorbing the short-wavelength light within solar light effectively. Additionally, when CuₓZn_{y}In_{z}S_{w} film is provided to the photo-absorbing layer in the top cell of multi-junction solar cell, it is possible that the multi-junction solar cell is composed so as to have excellent conversion efficiency for short-wavelength light.

### Preparation Example 2 of Solar Cell

In this example, the base plate 21 formed of soda-lime glass was used. Mo was stacked on the base plate 21 by sputtering so as to become the first electrode 22 having the thickness of approximately 0.4 micro meters. At sputtering Mo, Mo was used as target, Ar gas was filled the atmosphere within the instrument for sputtering, and the sputtering was carried out by the applied power of DC 1 kW.

Next, the photo-absorbing layer 23 consisting of CuₓZn_{y}(In, Ga)_{z}Se_{w} film was formed on the first electrode 22 so as to have thickness of 2 micro meters. For forming the photo-absorbing layer 23, the deposition rate from evaporation source in each Cu, Zn, In, Ga, and Se was controlled, and the photo-absorbing layer 23 was stacked on the first electrode 22 in maximum base plate temperature of 550° C. The deposition rate is controlled so that the molar ratios of Zn/(Cu+In+Ga+Zn), Ga/(In+Ga), Cu/(In+Ga) within the CuₓZn_{y}(In, Ga)_{z}Se_{w} film are 0.25, 0.15 and 1.1, respectively. The photo-absorption coefficient of photo-absorbing layer 23 was calculated by evaluating the transparency of photo-absorbing layer 23, and the band gap of photo-absorbing layer 23 was calculated from the photo-absorption coefficient. As a result, the value of band gap was 1.35 eV.

Next, CdS film having thickness of 80 nm was formed on the photo-absorbing layer 23 by the chemical precipitation method. For forming the CdS film, a water solution including cadmium nitratecadmium nitrate, thiourea and ammonia was warmed by 80° C., and the photo-absorbing layer 23 was soaked in the water solution. And then, ZnO film having the thickness of 0.1 micro meters was formed on the CdS film by sputtering. For forming the ZnO film, ZnO sintered compact was used as the target, Ar gas was filled the atmosphere within the instrument for sputtering, and the sputtering was carried out by the applied power of RF500W. Whereby, the window layer 24 consisting of CdS film and ZnO film was formed.

Next, the transparent second electrode 25 consisting of ZnO: Al was formed on the window layer 24 by sputtering so as to have thickness of 1 micro meter. For forming ZnO: Al film, ZnO sintered compact including Al₂O₃ of 2 wt % was used as the target, Ar gas including oxygen gas of 2 volume % was filled the atmosphere within the instrument for sputtering, and the sputtering was carried out by the applied power of DC 1 kW.

Whereby, the solar cell exemplified in FIG. 2 was obtained.

Additionally, the solar cell comprising a photo-absorbing layer consisting of Cu (In, Ga) Se₂ film which did not include Zn other than the photo-absorbing layer 23 was prepared by the same method described above. The Cu (In, Ga) Se₂ film was formed by the same evaporation method with the case of forming the CuₓZn_{y}(In, Ga)_{z}Se_{w} film. The molar ratio of Ga/(In+Ga) was adjusted to 0.6 so that the band gap of Cu (In, Ga) Se₂ film corresponded to that of CuₓZn_{y}(In, Ga)_{z}Se_{w} film. Moreover, the molar ratio of Cu/(In +Ga) within the Cu (In, Ga) Se₂ film was adjusted to 0.9.

The pseudo-solar light (1 kW/m², Air Mass: 1.5) was irradiated to the solar cell 20, and the property of current-voltage of solar cell 20 was measured at this time. The conductive efficiency of solar cell 20 was evolved. As a result, the conversion efficiency of solar cell comprising the Cu (In, Ga) Se₂ film was 10.1%, and the conversion efficiency of solar cell comprising the CuₓZn_{y}(In, Ga)_{z}Se_{w} film was 12.2%. Consequently, the solar cell comprising the CuₓZn_{y}(In, Ga)_{z}Se_{w} film was further improved so as to have good conversion efficiency in comparison with the case of Cu (In, Ga) Se₂ film.

When the open-circuit voltage and fill factor of each solar cells 20 was measured, the solar cell comprising the CuₓZn_{y}(In, Ga)_{z}Se_{w} film had larger values of open-circuit voltage and fill factor. Specifically, when the photo-absorbing layer was formed by depositing metals together, the gap was reduced while the crystal growth was promoted in the case that the molar ratio of Cu/(In+Ga) was larger than 1, and the low electric resistance compound being combined over-amount of Cu and Se separated out in the case that the molar ratio of Cu/(In+Ga) within Cu (In, Ga) Se₂ film which did not include Zn. Consequently, p-n combination between the window layer 24 having the property of n-type semiconductor and the photo-absorbing layer was not formed. On the other hand, it is thought that the precipitation of compound of Cu and Se is inhibited in the case of the CuₓZn_{y}(In, Ga)_{z}Se_{w} film including Zn of the group 12 elements.

From above results, it can be understood that the conversion efficiency of solar cell is effectively improved by comprising the CuₓZn_{y}(In, Ga)_{z}Se_{w} film as the photo-absorbing layer.

In the photo-absorbing layer consisting of the CuₓZn_{y}(In, Ga)_{z}Se_{w} film, when Ga was substituted to Al, the solar cell having excellent property as well as the case of the CuₓZn_{y}(In, Ga)_{z}Se_{w} film was obtained. Specifically, it is thought that the crystal structure and electrical property of the semiconductor does not vary even if Ga is substituted to Al.

In the photo-absorbing layer consisting of the CuₓZn_{y}(In, Ga)_{z}Se_{w} film, when one part of Cu of group 11 elements was also substituted to Ag, the solar cell having excellent property as well as the case of the CuₓZn_{y}(In, Ga)_{z}Se_{w} film was obtained. Specifically, it is thought that the crystal structure and electrical property of the semiconductor does not vary even if one part of Cu is substituted to Ag.

In the photo-absorbing layer consisting of the CuₓZn_{y}(In, Ga)_{z}Se_{w} film, when Zn of group 12 elements was also substituted to Cd, the solar cell having excellent property as well as the case of the CuₓZn_{y}(In, Ga)_{z}Se_{w} film was obtained. Specifically, it is thought that the crystal structure and electrical property of the semiconductor does not vary even if Zn is substituted to Cd.

In the photo-absorbing layer consisting of the CuₓZn_{y}(In, Ga)_{z}Se_{w} film, when Se of group 16 elements was also substituted to Te, the solar cell having excellent property as well as the case of the CuₓZn_{y}(In, Ga)_{z}Se_{w} film was obtained. Specifically, it is thought that the crystal structure and electrical property of the semiconductor does not vary even if Se is substituted to Te.

Additionally, when the solar cell comprising the photo-absorbing layer consisting of CuₓZn_{y}(In, Ga)_{z}Se_{w} film was carried out the heat treatment of 200 to 400° C. within the atmosphere including the oxygen, it was confirmed that the conversion efficiency of solar cell was increased in the range of 0.5 to 1.0%. Specifically, it is thought that oxygen fill holes where Se of the group 16 elements do not exist while the gap is reduced. Therefore, it is thought that the conductive efficiency of solar cell is effectively improved when the photo-absorbing layer including the group 12 elements, group 13 elements and group 16 elements further includes oxygen.

### EXPLAINING OF SIGNS

10: solar cell
15: photo-absorbing layer
20: solar cell
23: photo-absorbing layer

1-14. (canceled)

15. A solar cell comprising:
a semiconductor film,
wherein said semiconductor film is composed of a semiconductor, said semiconductor comprising group 11 elements, group 12 elements, group 13 elements and group 16 elements of the ratio indicated as a composition formula (1) in below,
AₓB_{y}C_{z}D_{w} (1)
wherein A, B, C and D indicate said group 11 elements, said group 12 elements, said group 13 elements and said group 16 elements, respectively, x, y, z and w are respectively numbers indicating a composition ratio, and x and z satisfy a relationship of x/z>1.

16. The solar cell according to claim 15, wherein x and z of said composition formula (1) satisfy a relationship of
1<x/z≦2.

17. The solar cell according to claim 15, wherein x, y and z of said composition formula (1) satisfy a relationship of
0<y/(x+y+z)≦0.6.

18. The solar cell according to claim 15, wherein x, y, z and w of said composition formula (1) satisfy a relationship of
0.8≦w/(x+y+z)≦1.2.

19. The solar cell according to claim 15, wherein
said semiconductor comprises:
at least either one of Cu and Ag as said group 11 elements,
at least either one of Zn and Cd as said group 12 elements,
at least any one of In, Ga and Al as said group 13 elements, and
at least any one of S, Se and Te as said group 16 elements.

20. The solar cell according to claim 15, wherein said semiconductor film comprises said group 1 elements.

21. The solar cell according to claim 15, wherein said semiconductor film comprises said group 2 elements.

22. The solar cell according to claim 15, wherein said semiconductor film comprises an oxygen.

23. The solar cell according to claim 15, wherein said semiconductor has a chalcopyrite structure.

24. The solar cell according to claim 15, wherein said semiconductor film has a p-type semiconductor property.

25. The solar cell according to claim 24, wherein said semiconductor film has an electric resistivity of 1 to 10⁷ Ωcm.

26. The solar cell according to claim 24, wherein said semiconductor film has a carrier concentration of 10¹¹ to 10¹⁹/cm³.

27. The solar cell according to claim 15, wherein said semiconductor film has a band gap of 1.0 to 2.0 eV.

28. The solar cell according to claim 15, wherein said semiconductor comprises at least S as group 16 elements.
